(19) United States
(12) Patent Application Publication
(10) Pub. No.: US 2026/0253887 A1
(43) Pub. Date: Aug. 27, 2026

(54) POSITIVE ELECTRODE MATERIAL, ELECTROCHEMICAL APPARATUS, AND ELECTRONIC APPARATUS

(71) Applicant: Dongguan Amperex Technology Limited, Dongguan (CN)

(72) Inventors: Gaofeng LI, Dongguan (CN); Shiyang CHENG, Dongguan (CN); Juan ZHOU, Dongguan (CN); Hui ZHANG, Dongguan (CN)

(73) Assignee: Dongguan Amperex Technology Limited, Dongguan (CN)

(21) Appl. No.: 19/652,369

(22) Filed: Apr. 20, 2026

Related U.S. Application Data
(63) Continuation of application No. PCT/CN2023/125757, filed on Oct. 20, 2023.

(51) Int. Cl. H01M 4/505; H01M 4/02; H01M 10/0567

(52) U.S. Cl. CPC H01M 4/505; H01M 10/0567; H01M 2004/021; H01M 2004/028

(57) ABSTRACT

A positive electrode material has a P63MC crystal system structure. In an XRD pattern of the positive electrode material, peaks are present respectively at 2θ of 17.6±0.3°, 37.3±0.3°, 40.6±0.3°, and 45.2±0.3°, where the peak at 17.6±0.2° is a (002) peak, the peak at 37.3±0.3° is a (101) peak, the peak at 40.6±0.3° is a (102) peak, and the peak at 45.2±0.3° is a (103) peak, where a ratio of a peak intensity of the (101) peak to a peak intensity of the (002) peak is 0.04 to 0.4, and a ratio of the peak intensity of the (101) peak to a peak intensity of the (103) peak is 0.4 to 3.0.

### CROSS REFERENCE TO RELATED APPLICATION

This application is a continuation application of International Application No. PCT/CN2023/125757, filed on Oct. 20, 2023, the contents of which are incorporated herein by reference in its entirety.

### TECHNICAL FIELD

This application relates to the field of energy storage, specifically, to a positive electrode material, an electrochemical apparatus, and an electronic apparatus.

### BACKGROUND

Due to the advantages of high energy density and low cost, ternary lithium-ion batteries have been widely used in fields such as power tools, electric bicycles, electric motorcycles, electric vehicles, and special equipment.

However, during the actual charge-discharge cycle of ternary positive electrode materials, transition metal ions in the transition metal layer undergo irreversible migration to the lithium layer, causing irreversible phase transformation of the structure. For example, the phase transformation from a layered structure to a spinel structure and from a layered structure to rock salt phase structure leads to serious voltage decay and capacity loss, which adversely affects the improvement of the cycling performance of lithium-ion batteries.

### SUMMARY

In order to solve the problems in the prior art, this application provides a positive electrode material, an electrochemical apparatus containing the same, and an electronic apparatus, to improve the cycling performance and high-temperature storage performance of the electrochemical apparatus.

In a first aspect, an object of this application is to provide a positive electrode material, where the positive electrode material has a P63MC crystal system structure; and in an XRD pattern of the positive electrode material, peaks are present respectively at 2θ of 17.6±0.3°, 37.3±0.3°, 40.6±0.3°, and 45.2±0.3°, where the peak at 17.6±0.2° is a (002) peak, the peak at 37.3±0.3° is a (101) peak, the peak at 40.6±0.3° is a (102) peak, and the peak at 45.2±0.3° is a (103) peak, where a ratio of a peak intensity of the (101) peak to a peak intensity of the (002) peak is 0.04 to 0.4, and a ratio of the peak intensity of the (101) peak to a peak intensity of the (103) peak is 0.4 to 3.0. The positive electrode material according to this application solves the irreversible phase transformation of ternary materials in the prior art, and the positive electrode material satisfying the above peak intensity ratio obtains an O2-phase layered transition metal oxide positive electrode material by changing the coordination mode of oxygen atoms and the stacking form of transition metals. Therefore, the positive electrode material in this application can improve the reversibility of lithium ion migration and effectively inhibit structural phase transformation, thereby improving structural stability and cycling stability.

According to some embodiments of this application, the positive electrode material includes Li element, and based on a weight of the positive electrode material, a content of the Li element is greater than 3 wt %. The positive electrode material having the above features can further improve the cycling performance and high-temperature storage performance of the electrochemical apparatus.

According to some embodiments of this application, a unit cell of the positive electrode material satisfies 2.5 Å<a<3.0 Å.

According to some embodiments of this application, a unit cell of the positive electrode material satisfies 8.5 Å<c<10.5 Å.

According to some embodiments of this application, a unit cell of the positive electrode material satisfies c/a>2.5.

When any of the above conditions for the unit cell parameter is satisfied, the crystal structure stability of the positive electrode material can be enhanced, thereby further improving the cycling performance and high-temperature storage performance of the electrochemical apparatus.

According to some embodiments of this application, in a Raman spectrum of the positive electrode material, a first peak is present at a wavelength of 496±10 cm⁻¹ and a second peak is present at 618±10 cm⁻¹, and a ratio of a peak intensity of the first peak to a peak intensity of the second peak is 0.45 to 0.68. The E_{g} peak near 496±10 cm⁻¹ corresponds to the O-M-O symmetric bending vibration peak, and the A_{1g} peak near 618±10 cm⁻¹ corresponds to the M-O symmetric stretching vibration peak.

According to some embodiments of this application, the positive electrode material includes a compound LiₓG_{y}(Niₐ₁Co_{b1}Mn_{c1}M_{d1})OₑQ_{f}, where 0.5<x+y≤0.8, 0≤a1≤1, 0b1≤1, 0≤c1≤1, 0≤d1≤1, 1.8≤e+f≤2.2, and a1, b1, c1, d1 are not simultaneously 0, where the element G includes Na and/or K, the element M includes at least one of Ca, Sr, Ba, Al, Fe, B, Mg, Si, S, Ti, Cr, Fe, Cu, Zn, Ga, Zr, Mo, W, Nb, In, Sn, Pb, Sb, Ce, La, or Hf, and the element Q includes at least one of F, Cl, Br, I, N, or P. The doping of the element G, the element M and the element Q increases a spacing for a lithium layer, changes the local coordination environment of transition metal atoms, and enhances the interaction between transition metals and oxygen atoms in the transition metal layer. The elements in the above positive electrode material synergistically inhibit the dissolution of transition metals or oxygen evolution, inhibit Li/Ni mixing, prevent the transformation from layered phase to spinel or rock salt phase during cycling, promote the diffusion of lithium ions, and further improve the structural stability, lithium ion utilization and rate performance of the material. Therefore, the positive electrode material has better cycling performance and can further reduce a thickness swelling rate of the electrochemical apparatus.

According to some embodiments of this application, a voltage-capacity differential curve (dQ/dV curve), obtained when a button cell formed by the positive electrode material and lithium metal is charged and discharged at 0.04 C in a voltage range of 2.5V to 4.5V, has at least one pair of redox peaks respectively in 2.5V to 3.1V and 3.5V to 4.5V. The positive electrode material having the above features further improves the cycling performance and high-temperature storage performance of the electrochemical apparatus.

According to some embodiments of this application, based on a mass of the positive electrode material, in a range of 2.5V to 3.1V, a button cell formed by the positive electrode material and lithium metal has a voltage-capacity differential curve (dQ/dV curve) whose peak intensity is 400 mAh/g/V to 1000 mAh/g/V. The positive electrode material within this characteristic peak intensity range further improves the cycling performance and high-temperature storage performance of the electrochemical apparatus.

According to some embodiments of this application, based on the mass of the positive electrode material, in a range of 3.5V to 4.5V, the button cell formed by the positive electrode material and lithium metal has a voltage-capacity differential curve (dQ/dV curve) whose peak intensity is 200 mAh/g/V to 600 mAh/g/V. The positive electrode material within this characteristic peak intensity range further improves the cycling performance and high-temperature storage performance of the electrochemical apparatus.

According to some embodiments of this application, for a button cell formed by the positive electrode material and lithium metal, when charged and discharged at a current of 0.04 C in a voltage range of 2.5V to 4.5V, a discharge curve in an obtained voltage-capacity curve has a sloping plateau at 3.5V to 4.3V, a specific capacity of the discharge curve in a range of 3.5V to 4.3V is Q1, and a total specific capacity in the range of 2.5V to 4.5V is Q2, where 0.4≤Q1/Q2≤0.7. The positive electrode material having the above features further improves the cycling performance and high-temperature storage performance of the electrochemical apparatus.

According to some embodiments of this application, when a button cell formed by the positive electrode material and lithium metal is charged to 4.5V, peaks are present respectively at 2θ of 18.6±0.3°, 37.9±0.3°, 41.5=0.3°, and 47.0±0.3° in the XRD pattern of the positive electrode material. The positive electrode material having the above features further improves the cycling performance and high-temperature storage performance of the electrochemical apparatus.

According to some embodiments of this application, when the button cell formed by the positive electrode material and lithium metal is discharged to 2.5V, peaks are present respectively at 2θ of 17.9±0.3°, 36.6=0.3°, 37.0±0.3°, 40.5=0.3°, and 45.7±0.3° in the XRD pattern of the positive electrode material. The positive electrode material having the above features further improves the cycling performance and high-temperature storage performance of the electrochemical apparatus.

According to some embodiments of this application, for a button cell formed by the positive electrode material and lithium metal, at a rate of 0.1 C in a voltage range of 2.8V to 4.5V, in a voltage-capacity differential curve (dQ/dV curve), a peak voltage of a reduction peak of 2.5V to 3.1V is V1, and a peak voltage of a reduction peak of 3.5V to 4.3V is V2, where 0.55≤V1/V2≤0.85. When the above range is satisfied, stress release during the phase transformation is facilitated, thereby further improving the cycling performance and high-temperature storage performance of the electrochemical apparatus.

In a second aspect, an object of this application is also to provide an electrochemical apparatus, including a positive electrode, where the positive electrode includes the positive electrode material in any of the foregoing embodiments. With the positive electrode material according to this application, the electrochemical apparatus according to this application has improved cycling performance, especially due to the inhibition of the irreversible phase transformation of the positive electrode material, the electrochemical apparatus according to this application has a significantly reduced thickness swelling rate when charged at high temperature.

According to some embodiments of this application, the electrochemical apparatus further includes an electrolyte solution, where the electrolyte solution includes a nitrile compound, and the nitrile compound includes at least one of the following:

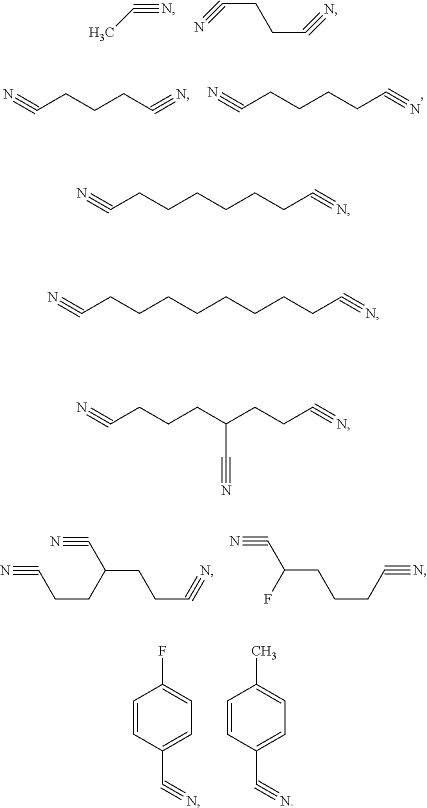

The positive electrode material in this application and the nitrile compound in the electrolyte solution can synergistically improve the stability of the positive electrode interface. The antioxidant effect of the nitrile compound is compatible with the positive electrode material in this application, and the two can jointly stabilize the electrode interface film without increasing impedance. Adding an electrolyte solution including a nitrile compound in the electrochemical apparatus according to this application further improves cycling performance and high-temperature storage performance.

According to some embodiments of this application, based on a mass of the electrolyte solution, a mass percentage of the nitrile compound is 0.1% to 8%. The electrolyte solution containing the nitrile compound satisfying the above range better facilitates the utilization of the plateau capacity of the material and the improvement of cycling stability, and further reduces the thickness swelling rate.

In a third aspect, this application provides an electronic apparatus, including any of the electrochemical apparatuses described in this application.

### BRIEF DESCRIPTION OF DRAWINGS

FIG. 1A schematically shows a SEM image of a positive electrode material in Example 1 of this application;

FIG. 1B schematically shows a SEM image of the positive electrode material in Example 1 of this application;

FIG. 2 schematically shows an XRD pattern of the positive electrode material in Example 1 of this application;

FIG. 3 schematically shows a Raman spectrum of the positive electrode material in Example 1 of this application;

FIG. 4 schematically shows a dQ/dV curve of a button cell in Example 1 of this application; and

FIG. 5 schematically shows a charge-discharge curve of the button cell in Example 1 of this application.

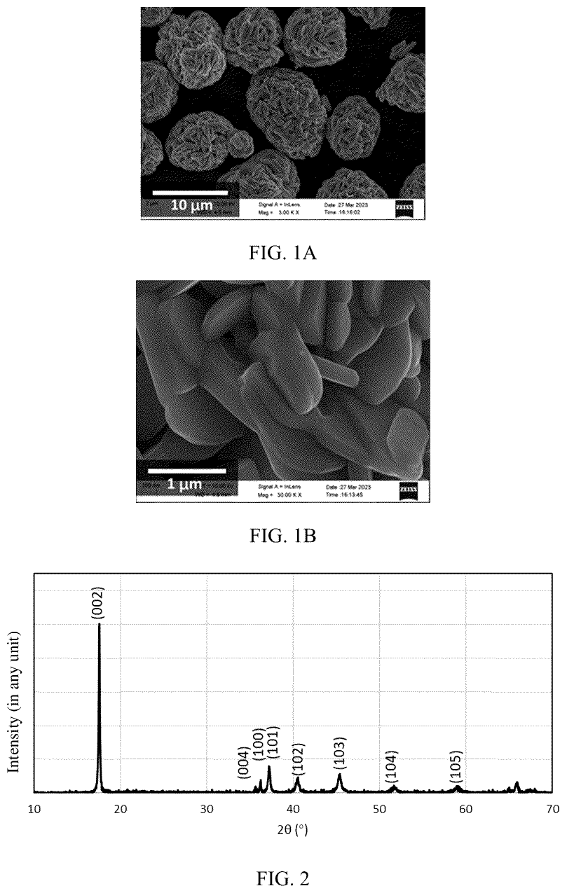

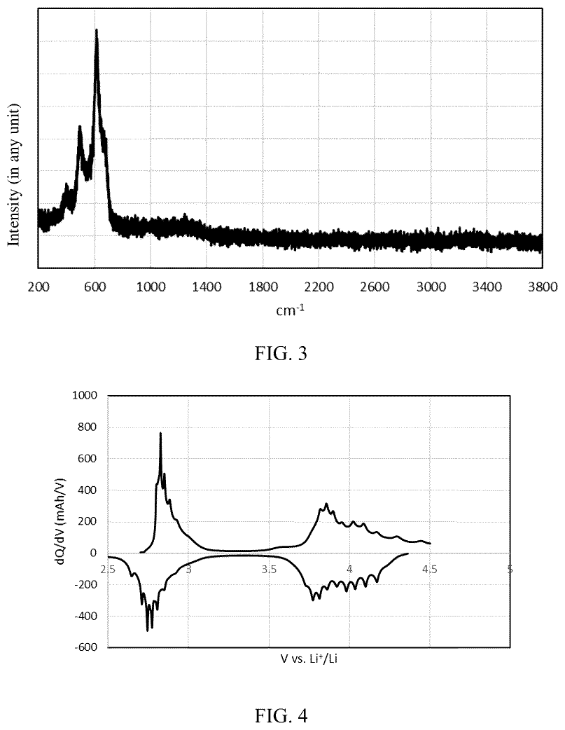

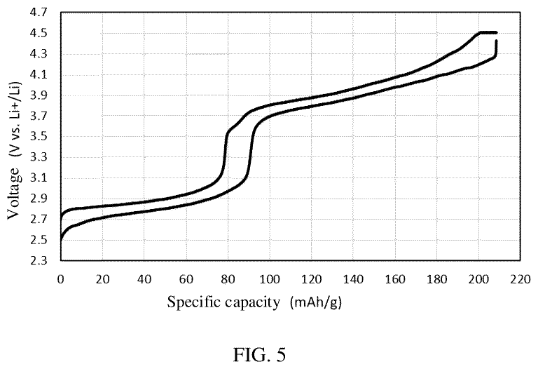

### DETAILED DESCRIPTION

In order to make the objectives, technical solutions and advantages of this application clearer, the technical solutions of this application will be clearly and completely described below with reference to some embodiments. It is clear that the described embodiments are some but not all embodiments of this application. The related embodiments described herein are illustrative in nature and are used to provide a basic understanding of this application. These embodiments of this application should not be construed as limitations to this application.

For brevity, only some numerical ranges are specifically disclosed herein. However, any lower limit may be combined with any upper limit to form a range not explicitly recited; and any lower limit may be combined with other lower limits to form ranges not explicitly recited, and similarly any upper limit may be combined with any other upper limit to form a range not explicitly recited. Furthermore, each individual point or single numerical value disclosed may be used as a lower limit or upper limit in combination with any other point or single numerical value or with another lower limit or upper limit to form a range not explicitly recited.

In the description herein, unless otherwise specified, “above” and “below” include the reference number.

Unless otherwise specified, the terms used in this application have the ordinary meanings understood by those skilled in the art. Unless otherwise specified, the values of various parameters mentioned in this application can be measured by using various measurement methods commonly used in the art (for example, testing can be performed according to the methods given in some embodiments of this application).

A list of items connected by the term “at least one of”, “at least one in”, “at least one kind of” or other similar terms may mean any combination of the listed items. For example, if items A and B are listed, then the phrase “at least one of A and B” means only A; only B; or A and B. In another example, if items A, B and C are listed, then the phrase “at least one of A, B and C” means only A; only B; only C; A and B (excluding C); A and C (excluding B); B and C (excluding A); or all of A, B and C. Item A may include a single component or multiple components. Item B may include a single component or multiple components. Item C may include a single component or multiple components.

In the context of this application, “a material has a P63MC crystal system structure” means that those skilled in the art can determine from the XRD pattern of the material that the material has a P63MC crystal system based on knowledge common in the art.

### I. Positive Electrode Material

In a first aspect, this application provides a positive electrode material. The positive electrode material has a P63MC crystal system structure. In the XRD pattern of the positive electrode material, peaks are present respectively at 2θ of 17.6±0.3°, 37.3±0.3°, 40.6±0.3°, and 45.2±0.3°, where the peak at 17.6±0.2° is the (002) peak, the peak at 37.3±0.3° is the (101) peak, the peak at 40.6±0.3° is the (102) peak, and the peak at 45.2±0.3° is the (103) peak, where a ratio of a peak intensity of the (101) peak to a peak intensity of the (002) peak is 0.04 to 0.4, for example 0.04, 0.06, 0.08, 0.10, 0.12, 0.14, 0.16, 0.18, 0.20, 0.22, 0.24, 0.26, 0.28, 0.30, 0.32, 0.34, 0.36, 0.38, and 0.40 or in any range defined by these values, and a ratio of a peak intensity of the (101) peak to a peak intensity of the (103) peak is 0.4 to 3.0, for example 0.4, 0.6, 0.8, 1.0, 1.2, 1.4, 1.6, 1.8, 2.0, 2.2, 2.4, 2.6, 2.8, and 3.0 or in any range defined by these values.

In some embodiments, the positive electrode material includes the Li element, and based on a weight of the positive electrode material, a content of the Li element is greater than 3 wt %, for example the content of the Li element is 3.2 wt %, 3.4 wt %, 3.6 wt %, 3.8 wt %, 4.0 wt %, 4.2 wt %, 4.4 wt %, 4.6 wt %, 4.8 wt %, and 5.0 wt % or in any range defined by these values.

In some embodiments, unit cell parameters of the positive electrode material satisfy 2.5 Å<a<3.0 Å, for example, a may be 2.6 Å, 2.7 Å, 2.8 Å, or 2.9 Å, or in any range defined by these values.

In some embodiments, the unit cell parameters of the positive electrode material satisfy 8.5 Å<c<10.5 Å, for example, c may be 8.6 Å, 8.7 Å, 8.8 Å, 8.9 Å, 9.0 Å, 9.1 Å, 9.2 Å, 9.3 Å, 9.4 Å, 9.5 Å, 9.6 Å, 9.7 Å, 9.8 Å, 9.9 Å, 10.0 Å, 10.1 Å, 10.2 Å, 10.3 Å, or 10.4 Å, or in any range defined by these values.

In some embodiments, the unit cell parameters of the positive electrode material satisfy c/a>2.5, for example, c/a may be 2.6, 2.8, 3.0, 3.2, 3.4, 3.6, 3.8, 4.0, or in any range defined by these values.

In some embodiments, in the Raman spectrum of the positive electrode material, a first peak is present at a wavelength of 496±10 cm⁻¹ and a second peak is present at 618±10 cm⁻¹, where a ratio of a peak intensity of the first peak to a peak intensity of the second peak is 0.45 to 0.68, for example, 0.45, 0.46, 0.47, 0.48, 0.49, 0.50, 0.51, 0.52, 0.53, 0.54, 0.55, 0.56, 0.57, 0.58, 0.59, 0.60, 0.61, 0.62, 0.63, 0.64, 0.65, 0.66, 0.67, or 0.68, or in any range defined by these values.

In some embodiments, the positive electrode material includes a compound LiₓG_{y}(Niₐ₁Co_{b1}Mn_{c1}M_{d1})OₑQ_{f}, where 0.5<x+y≤0.8, 0≤a1≤1, 0≤b1≤1, 0≤c1≤1, 0≤d1≤1, 1.8≤e+f≤2.2, and a1, b1, c1, d1 are not simultaneously 0, where the element G includes Na and/or K, the element M includes at least one of Ca, Sr, Ba, Al, Fe, B, Mg, Si, S, Ti, Cr, Fe, Cu, Zn, Ga, Zr, Mo, W, Nb, In, Sn, Pb, Sb, Ce, La, or Hf, and the element Q includes at least one of F, Cl, Br, I, N, or P.

In some embodiments, a voltage-capacity differential curve (dQ/dV curve), obtained when a button cell formed by the positive electrode material and lithium metal is charged and discharged at a current of 0.04 C in a voltage range of 2.5V to 4.5V, has at least one pair of redox peaks respectively in a voltage range of 2.5V to 3.1V and a voltage range of 3.5V to 4.5V.

In some embodiments, based on a mass of the positive electrode material, when the button cell formed by the positive electrode material and lithium metal is charged and discharged at a current of 0.04 C in a range of 2.5V to 3.1V, a peak intensity of an obtained voltage-capacity differential curve (dQ/dV curve) is 400 mAh/g/V to 1000 mAh/g/V, for example 400 mAh/g/V, 450 mAh/g/V, 500 mAh/g/V, 550 mAh/g/V, 600 mAh/g/V, 650 mAh/g/V, 700 mAh/g/V, 750 mAh/g/V, 800 mAh/g/V, 850 mAh/g/V, 900 mAh/g/V, 950 mAh/g/V, or 1000 mAh/g/V, or in any range defined by these values.

In some embodiments, based on the mass of the positive electrode material, when a button cell formed by the positive electrode material and lithium metal is charged and discharged at a current of 0.04 C in a range of 3.5V to 4.5V, a peak intensity of an obtained voltage-capacity differential curve (dQ/dV curve) is 200 mAh/g/V to 600 mAh/g/V, for example 200 mAh/g/V, 250 mAh/g/V, 300 mAh/g/V, 350 mAh/g/V, 400 mAh/g/V, 450 mAh/g/V, 500 mAh/g/V, 550 mAh/g/V, or 600 mAh/g/V, or in any range defined by these values.

In some embodiments, for a button cell formed by the positive electrode material and lithium metal, when charged and discharged at a current of 0.04 C in a voltage range of 2.5V to 4.5V, a discharge curve in an obtained voltage-capacity curve has a sloping plateau at 3.5V to 4.3V, a specific capacity of the discharge curve in a range of 3.5V to 4.3V is Q1, and a total specific capacity in the range of 2.5V to 4.5V is Q2, where a value of Q1/Q2 is 0.4 to 0.7, for example 0.4, 0.5, 0.6, or 0.7, or in any range defined by these values.

In some embodiments, when a button cell formed by the positive electrode material and lithium metal is charged to 4.5V, peaks are present respectively at 2θ of 18.6±0.3°, 37.9±10.3°, 41.5±0.3°, and 47.0±0.3° in the XRD pattern of the positive electrode material.

In some embodiments, when the button cell formed by the positive electrode material and lithium metal is discharged to 2.5V, peaks are present respectively at 2θ of 17.9±0.3°, 36.6±0.3°, 37.0±0.3°, 40.5±0.3°, and 45.7±0.3° in the XRD pattern of the positive electrode material.

In some embodiments, for a button cell formed by the positive electrode material and lithium metal, at a rate of 0.1 C in a voltage range of 2.8V to 4.5V, in a voltage-capacity differential curve (dQ/dV curve), a peak voltage of a reduction peak of 2.5V to 3.1V is V1, and a peak voltage of a reduction peak of 3.5V to 4.3V is V2, where 0.55≤V1/V2≤0.85, for example, 0.55, 0.60, 0.65, 0.70, 0.75, 0.80, or 0.85, or in any range defined by these values.

### II. Electrochemical Apparatus

In a second aspect, this application further provides an electrochemical apparatus, including a positive electrode, where the positive electrode includes the positive electrode material described in the first aspect of this application.

In some embodiments, the positive electrode further includes a conductive agent and a binder. In some embodiments, the binder includes, but is not limited to: polyvinyl alcohol, hydroxypropyl cellulose, diacetate cellulose, polyvinyl chloride, carboxylated polyvinyl chloride, polyviny fluoride, ethylene oxide-containing polymer, polyvinylpyrrolidone, polyurethane, polytetrafluoroethylene, poly(1,1-difluoroethylene), polyethylene, polypropylene, butadiene styrene rubber, acrylic (ester)-modified butadiene styrene rubber, epoxy resin, nylon, or the like. In some embodiments, the conductive agent includes, but is not limited to, a carbon-based material, metal-based material, conductive polymer, and mixtures thereof. In some embodiments, the carbon-based material includes at least one of natural graphite, artificial graphite, carbon black, acetylene black, Ketjen black or carbon fibers. In some embodiments, the metal-based material includes at least one of metal powder, metal fibers, copper, nickel, aluminum or silver. In some embodiments, the conductive polymer is a polyphenylene derivative.

In some embodiments, the positive electrode further includes a positive electrode current collector. In some embodiments, the positive electrode current collector may be a metal foil or a composite current collector. For example, aluminum foil may be used. The composite current collector may be formed by forming a metal material (copper, copper alloy, nickel, nickel alloy, titanium, titanium alloy, silver, silver alloy, or the like) on a polymer substrate.

The positive electrode in this application can be prepared by using known methods in the art. Typically, the positive electrode material, optional conductive agent (such as a carbon material like carbon black and metal particles), binder (such as SBR), other optional additives (such as PTC thermistor material), and other materials are mixed and dispersed in a solvent (such as deionized water), stirred uniformly, then uniformly applied to the positive electrode current collector, and dried to obtain the positive electrode including a positive electrode film sheet.

In some embodiments, the electrochemical apparatus further includes a negative electrode.

In some embodiments, the negative electrode includes a negative electrode current collector and a negative electrode active material layer disposed on a surface of the negative electrode current collector. In some embodiments, the negative electrode active material layer includes a negative electrode active material, and the negative electrode active material may include a material on which lithium ions reversibly intercalate/deintercalate, lithium metal, lithium metal alloy or transition metal oxide. In some embodiments, the negative electrode active material includes at least one of a carbon material or silicon material. The carbon material includes at least one of graphite or hard carbon, and the silicon material includes at least one of silicon, silicon-oxygen compound, silicon-carbon compound, or silicon alloy. In some embodiments, the negative electrode active material layer includes an binder, and the binder may include various binder polymers. In some embodiments, the binder includes at least one of polyvinylidene fluoride, vinylidene fluoride-hexafluoropropylene copolymer, polyamide, polyacrylonitrile, polyacrylate, polyacrylic acid, polyacrylate salt, sodium carboxymethyl cellulose, polyvinylpyrrolidone, polyvinyl ether, polymethyl methacrylate, polytetrafluoroethylene, polyhexafluoropropylene or butadiene styrene rubber. In some embodiments, the negative electrode active material layer further includes a conductive material to improve electrode conductivity. Any conductive material may be used as the conductive material as long as it does not cause chemical changes. In some embodiments, the conductive material includes at least one of conductive carbon black, acetylene black, carbon nanotubes, Ketjen black, conductive graphite or graphene.

In some embodiments, the negative electrode is lithium metal or a lithium-containing alloy. In some embodiments, the negative electrode is lithium metal.

In some embodiments, the electrochemical apparatus further includes an electrolyte solution or a solid-state electrolyte.

In some embodiments, the electrolyte solution used in some embodiments of this application may be an electrolyte solution known in the prior art.

In some embodiments, the electrolyte solution includes an organic solvent, a lithium salt, and an additive. The organic solvent of the electrolyte solution according to this application may be any organic solvent known in the prior art that can be used as a solvent for the electrolyte solution. There is no limitation on the electrolyte used in the electrolyte solution according to this application, and it may be any electrolyte known in the prior art. The additive of the electrolyte solution according to this application may be any additive known in the prior art that can be used as an electrolyte solution additive. In some embodiments, the organic solvent includes, but is not limited to, ethylene carbonate (EC), propylene carbonate (PC), diethyl carbonate (DEC), ethyl methyl carbonate (EMC), dimethyl carbonate (DMC), propylene carbonate, or ethyl propionate. In some embodiments, the organic solvent includes an ether solvent, for example, at least one of 1,3-dioxolane (DOL) or ethylene glycol dimethyl ether (DME). In some embodiments, the lithium salt includes at least one of organic lithium salt or inorganic lithium salt. In some embodiments, the lithium salt includes, but is not limited to, lithium hexafluorophosphate (LiPF₆), lithium tetrafluoroborate (LiBF₄), lithium difluorophosphate (LiPO₂F₂), lithium bis(trifluoromethanesulfonyl)imide LiN(CF₃SO₂)₂ (LiTFSI), lithium bis(fluorosulfonyl)imide Li(N(SO₂F)₂) (LiFSI), lithium bis(oxalato) borate LiB(C₂O₄)₂ (LiBOB), or lithium difluoro (oxalato) borate LiBF₂(C₂O₄) (LiDFOB).

In some embodiments, the electrolyte solution includes a nitrile compound, and the nitrile compound includes at least one of the following compounds:

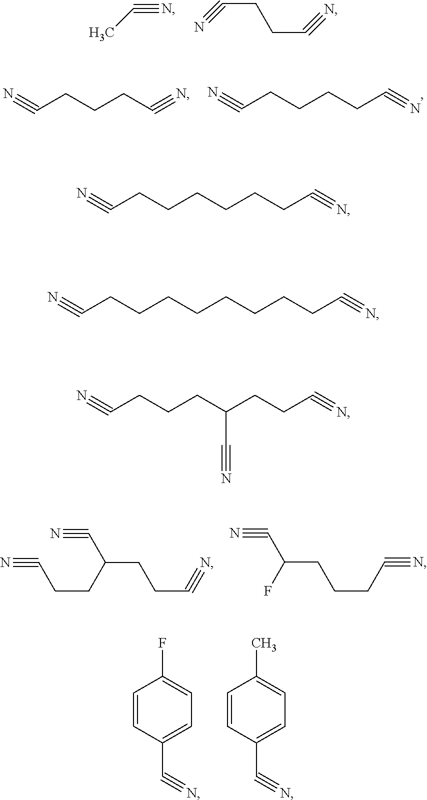

In some embodiments, based on a mass of the electrolyte solution, a mass percentage of the nitrile compound is 0.1% to 8%, for example, 0.1%, 0.5%, 1.0%, 1.5%, 2.0%, 2.5%, 3.0%, 3.5%, 4.0%, 4.5%, 5.0%, 5.5%, 6.0%, 6.5%, 7.0%, 7.5%, or 8.0%, or in any range defined by these values.

In some embodiments, in the electrochemical apparatus, a separator is provided between the positive electrode and the negative electrode to prevent short circuit. A material and shape of the separator used in some embodiments of this application are not particularly limited, and it may be any technology disclosed in the prior art. In some embodiments, the separator may include a polymer, inorganic material, or the like formed by a material stable to the electrolyte solution in this application. For example, the separator may include a substrate layer and a surface treatment layer. The substrate layer is a non-woven fabric, film or composite film having a porous structure, and a material of the substrate layer includes at least one of polyethylene, polypropylene, polyethylene terephthalate, or polyimide. Specifically, a polypropylene porous film, polyethylene porous film, polypropylene non-woven fabric, polyethylene non-woven fabric, or polypropylene-polyethylene-polypropylene porous composite film may be used. A surface treatment layer is provided on at least one surface of the substrate layer, and the surface treatment layer may be a polymer layer or an inorganic layer, or a layer formed by mixing a polymer and an inorganic material. The inorganic layer includes inorganic particles and a binder, and the inorganic particles include at least one of alumina, silica, magnesia, titania, hafnia, tin oxide, ceria, nickel oxide, zinc oxide, calcia, zirconia, yttria, silicon carbide, boehmite, aluminum hydroxide, magnesium hydroxide, calcium hydroxide, or barium sulfate. The binder includes at least one of polyvinylidene fluoride, vinylidene fluoride-hexafluoropropylene copolymer, polyamide, polyacrylonitrile, polyacrylate, polyacrylic acid, polyacrylate salt, polyvinylpyrrolidone, polyvinyl ether, polymethyl methacrylate, polytetrafluoroethylene, or polyhexafluoropropylene. The polymer layer includes a polymer, and a material of the polymer includes at least one of polyamide, polyacrylonitrile, acrylate polymer, polyacrylic acid, polyacrylate salt, polyvinylpyrrolidone, polyvinyl ether, polyvinylidene fluoride, or poly(vinylidene fluoride-hexafluoropropylene).

According to some embodiments of this application, the electrochemical apparatus in this application includes, but is not limited to, all kinds of primary batteries, secondary batteries, fuel cells, solar cells, or capacitors. In some embodiments, the electrochemical apparatus is a lithium secondary battery. In some embodiments, the lithium secondary battery includes, but is not limited to, lithium metal secondary battery, lithium-ion secondary battery, lithium polymer secondary battery, or lithium ion polymer secondary battery.

### III. Electronic Apparatus

In a third aspect, the electronic apparatus in this application includes the electrochemical apparatus described in the second aspect of this application.

In some embodiments, the electronic apparatus includes, but is not limited to, notebook computer, pen-input computer, mobile computer, e-book player, portable phone, portable fax machine, portable copier, portable printer, headphone stereo, video recorder, liquid crystal television, handheld cleaner, portable CD player, mini disc, transceiver, electronic organizer, calculator, memory card, portable recorder, radio, backup power supply, motor, automobile, motorcycle, power-assisted bicycle, bicycle, lighting fixture, toy, game console, clock, power tool, flashlight, camera, household large-scale storage battery, lithium-ion capacitor, or the like.

### EXAMPLES AND COMPARATIVE EXAMPLES

### Example 1

### Preparation of Positive Electrode Material

(1) Mn₂O₃ and Ni(OH)₂ (molar ratio Ni:Mn=1:2) were ground and mixed uniformly with sodium carbonate according to the doping ratio shown in Table 1, where doping ratio-moles of doping element/(moles of manganese element+moles of nickel element); then calcined at 850° C. in air atmosphere for 20 h; and cooled to 600° C. at a rate of 10° C./min. Then a mixed gas of N₂ and H₂ was introduced. Volume fractions of N₂ and H₂ in the mixed gas were given in Table 1. After holding at 600° C. for 6 h, the mixture was quenched to room temperature at a rate of 10° C./min to obtain a sodium-containing oxide intermediate.

(2) The above sodium-containing oxide intermediate was added to a mixed aqueous solution of 4.8 mol/L LiOH and LiCl at 60° C. (Li was in 12-fold excess, and a molar ratio of LiOH to LiCl was 1.5:1) and fully stirred for reactions for 2 to 3 days. After the reactions, a solid product was filtered and fully washed with deionized water to obtain the positive electrode material.

### Examples 2 and 3

For the preparation method of the positive electrode material provided in this example, reference may be made to Example 1, and a difference was that the stirring reaction time in step (2) was 20 h.

### Examples 4 and 5

For the preparation method of the positive electrode material provided in this example, reference may be made to Example 1, and a difference was that in step (1), potassium carbonate was doped according to the doping ratio shown in Table 1.

### Examples 6 to 11

For the preparation method of the positive electrode material provided in this example, reference may be made to Example 1, and a difference was that in step (1), nano magnesia was doped according to the doping ratio shown in Table 1.

### Examples 12 to 17

For the preparation method of the positive electrode material provided in this example, reference may be made to Example 1, and a difference was that in step (1), calcia was doped according to the doping ratio shown in Table 1.

### Examples 18 to 20

For the preparation method of the positive electrode material provided in this example, reference may be made to Example 1, and a difference was that in step (1), alumina was doped according to the doping ratio shown in Table 1.

### Examples 21 to 23

For the preparation method of the positive electrode material provided in this example, reference may be made to Example 1, and a difference was that in step (1), alumina was doped according to the doping ratio shown in Table 1.

### Comparative Example 1

Preparation of positive electrode material: (1) A mixed solution containing NiSO₄, CoSO₄ and MnSO₄ was prepared according to the elemental molar ratio Ni:Co:Mn=5:2:3; and was mixed and reacted with a precipitating agent (NaOH solution) and a complexing agent (ammonia solution), to obtain a precursor Ni_{0.5}Co_{0.2}Mn_{0.3}(OH)₂ by controlling a reaction time, ammonia solution concentration and pH value. (2) The precursor in the above step and lithium carbonate were ground and mixed uniformly in a certain ratio, calcined at 850° C. in air atmosphere for 20 h, cooled to room temperature at a certain rate, and finally crushed and sieved to obtain an O3-phase positive electrode material.

### Preparation of Lithium-Ion Battery

### (1) Preparation of Lithium-Ion Button Cell

Positive electrode sheet: A positive electrode slurry was prepared from a binder polyvinylidene fluoride (PVDF), a conductive agent conductive carbon black (Super P) and a positive electrode active material in a certain weight ratio (1.5:1.5:97); a viscosity of the positive electrode slurry was adjusted to about 3000 mPa·s to about 6000 mPa·s; the mixed slurry was uniformly applied to two sides of an aluminum foil, with a coating thickness on one side being 200 μm; after drying, rolling was performed to form a required electrode, where a humidity of an electrode processing and transportation environment was 45%. A coated electrode areal density was 13 mg/cm². The positive electrode sheet was obtained after drying, and punched into 14 mm discs to prepare a positive electrode sheet with one side coated.

Separator: The separator was punched into 18 mm discs.

Negative electrode sheet: The negative electrode sheet was a lithium metal sheet with a diameter of 18 mm.

Electrolyte solution: In a dry argon environment, propylene carbonate (PC), ethylene carbonate (EC), diethyl carbonate (DEC) (weight ratio of PC:EC:DEC was 1:1:1) were mixed to obtain a solvent, and LiPF₆ was added and mixed uniformly to obtain the electrolyte solution. Based on a mass of the electrolyte solution, a mass percentage of LiPF₆ was 12.5%.

Assembly of button cell: The positive electrode sheet, separator, negative electrode sheet (lithium metal sheet), electrolyte solution, battery case and other accessories were transferred into a glove box (water content was less than 11 ppm). The battery was assembled in the stacking order from bottom to top and the electrolyte solution was injected: negative electrode case>spacer+electrolyte solution>lithium metal sheet+electrolyte solution>one layer of separator+electrolyte solution>positive electrode sheet+electrolyte solution>spacer+electrolyte solution>spring clip>positive electrode case. The battery was sealed on a sealing machine to obtain the button cell.

### (2) Preparation of Lithium-Ion Pouch Battery

Preparation of positive electrode: A positive electrode slurry was prepared from a binder polyvinylidene fluoride (PVDF), a conductive agent conductive carbon black (Super P) and a positive electrode material in a certain weight ratio (1.5:1.5:97). A viscosity of the positive electrode slurry was adjusted to about 3000 mPa·s to about 6000 mPa·s; the mixed slurry was uniformly applied to two sides of an aluminum foil, with a coating thickness on one side being 200 μm; and after drying, rolling was performed to form the required electrode, where a humidity of the electrode processing and transportation environment was 45%. A coated electrode areal density was 13 mg/cm². The positive electrode sheet was obtained after drying, and punched into 14 mm discs to prepare a positive electrode sheet with one side coated.

Preparation of negative electrode: Artificial graphite, butadiene styrene rubber and sodium carboxymethyl cellulose (CMC) were mixed with deionized water in a weight ratio of 96%:2%:2%, stirred uniformly to obtain a negative electrode slurry. The negative electrode slurry was applied to a copper foil with a thickness of 12 μm. The negative electrode was obtained through drying, cold pressing, cutting, and tab welding.

Preparation of electrolyte solution: In a dry argon environment, propylene carbonate (PC), ethylene carbonate (EC), diethyl carbonate (DEC) (weight ratio of PC:EC:DEC was 1:1:1) were mixed to obtain a solvent, and LiPF₆ was added and mixed uniformly to obtain the electrolyte solution. Based on a mass of the electrolyte solution, a mass percentage content of LiPF₆ was 12.5%.

Preparation of separator: A polyethylene (PE) porous polymer film was used as the separator.

Assembly of lithium-ion pouch battery: The positive electrode, separator and negative electrode were stacked in order, with the separator placed between the positive electrode and negative electrode for separation. A bare cell was obtained through winding. The bare cell was placed in an outer package and sealed after the electrolyte solution was injected. After formation, degassing, trimming and other process steps, a lithium-ion pouch battery was obtained.

### Examples 24 to 28

The difference from Example 1 was that, on the basis of Example 1, an additive (nitrile compound) was further added to the electrolyte solution, and types and contents of the additives in the examples and the performance of the corresponding lithium-ion batteries were shown in Table 2 below.

### Test Methods

### 1. Cycling Capacity Retention Rate of Lithium-Ion Pouch Battery

45° C. cycling capacity retention rate test: At 45° C., measurement was performed at a 1.5 C charge current and 4 C discharge current. A discharge specific capacity at the 2nd cycle was used as the reference for cycling specific capacity decay, where cycling capacity retention rate at the nth cycle=discharge capacity at the nth cycle/discharge capacity at the 2nd cycle×100%, for example, cycling capacity retention rate at the 300th cycle-discharge capacity at the 300th cycle/discharge capacity at the 2nd cycle×100%.

25° C. cycling capacity retention rate test: At 25° C., measurement was performed at a 1.5 C charge current and 4 C discharge current. A discharge specific capacity at the 2nd cycle was used as the reference for cycling specific capacity decay, where cycling capacity retention rate at the nth cycle=discharge capacity at the nth cycle/discharge capacity at the 2nd cycle×100%, For example, cycling capacity retention rate at the 300th cycle=discharge capacity at the 300th cycle/discharge capacity at the 2nd cycle×100%.

2. Voltage-Capacity Curve, dQ/dV Curve, and Q1/Q2 Test

At 25° C., the button cell was charged at a current of 0.04 C in the voltage range of 2.5V to 4.5V, charged to 4.5V at a constant current, and then charged at the constant voltage of 4.5V until the current was 50 μA; then the battery was discharged at a constant current of 0.04 C until the lower limit voltage was 2.5V, to obtain the voltage-capacity curve and voltage-capacity differential curve (dQ/dV curve). According to the discharge curve in the capacity-voltage relationship curve, the specific capacity of the button cell in the voltage range of 3.5V to 4.3V was obtained as Q1, and the total specific capacity in 2.5V to 4.5V as Q2.

### 3. XRD Test

An X-ray diffractometer (XRD, instrument model: Bruker D8 ADVANCE) was used to test the positive electrode material, target was Cu Kα, voltage and current were 40 kV/35 mA, scanning angle range was 10° to 60°, and a scanning rate was 5°/min.

### 4. SEM Test

Scanning electron microscopy characterization was recorded by ZEISS (Sigma-02-33) scanning electron microscope. The test was conducted at 10 kV and 2.335 A.

### 5. Test Method for Thickness Swelling Rate

At 85° C., the lithium-ion pouch battery was charged to 4.35V at a 1.5 C charge current. The lithium-ion pouch battery was clamped with two hard metal plates, and the thickness change on both sides of the metal plate was tested with a micrometer, where thickness swelling rate=100×(thickness after swelling-thickness before swelling)/thickness before swelling.

### 6. Raman Test Method

A Raman spectroscopy (Raman) instrument (instrument model: HR Evolution) was used to test the positive electrode material, a test wavelength was 532 nm, and laser power was 100 mW.

### Test Results

According to the method described in this application, button cells and lithium-ion pouch batteries were prepared with the positive electrode materials obtained in the comparative example and examples and subjected to the above tests. The test results were shown in Table 1 and Table 2.

TABLE 1

| | | | | | | | | | | | Reduc- | Reduct- | |
|---|---|---|---|---|---|---|---|---|---|---|---|---|---|
| | | | | | | | | | | | tion | ion | |
| | | | | | | | | | Reduc- | Reduc- | peak | peak | |
| | | | | | | | | | tion | tion | inten- | inten- | |
| | | | | | | | | | peak | peak | sity in | sity in | |
| | | | | | | | (101)/ | (101)/ | voltage | voltage | dQ/dV | dQ/dV | |
| | | | | | | | (103) | (002) | in dQ/ | indQ/ | (mAh/ | (mAh/ | |
| | | | | | | | peak | peak | dV (V) | dV (V) | g/V) | g/V) | |
| | | | | | | | inten- | inten- | (2.5V | (3.5V | (2.5V | (3.5V | |
| | Doping | Doping | | | | | sity | sity | to | to | to | to | Q1/ |
| No. | element | ratio | N₂ | H₂ | a | c/a | ratio | ratio | 3.1V) | 4.5V) | 3.1V) | 4.5V) | Q2 |
| Comparative | / | 0 | 0 | 0 | / | / | / | / | / | / | / | / | / |
| example 1 | | | | | | | | | | | | | |
| Example 1 | Na | 0 | 99% | 1% | 2.859 | 3.52 | 1.33 | 0.16 | 2.74 | 3.78 | 490 | 297 | 0.56 |
| Example 2 | Na | 0.03 | 99% | 1% | 2.855 | 3.58 | 1.30 | 0.18 | 2.76 | 3.81 | 510 | 310 | 0.58 |
| Example 3 | Na | 0.03 | 98% | 2% | 2.857 | 3.59 | 1.80 | 0.25 | 2.87 | 3.85 | 470 | 340 | 0.62 |
| Example 4 | K | 0.04 | 98% | 2% | 2.851 | 3.60 | 3.40 | 0.37 | 2.92 | 3.76 | 500 | 420 | 0.66 |
| Example 5 | K | 0.04 | 90% | 10% | 2.850 | 3.61 | 3.31 | 0.34 | 2.94 | 3.81 | 450 | 300 | 0.61 |
| Example 6 | Mg | 0.01 | 99% | 1% | 2.861 | 3.52 | 1.03 | 0.14 | 2.71 | 3.78 | 460 | 310 | 0.60 |
| Example 7 | Mg | 0.03 | 99% | 1% | 2.859 | 3.57 | 1.07 | 0.16 | 2.70 | 3.74 | 455 | 290 | 0.55 |
| Example 8 | Mg | 0.05 | 99% | 1% | 2.858 | 3.55 | 1.14 | 0.15 | 2.66 | 3.70 | 444 | 287 | 0.57 |
| Example 9 | Mg | 0.01 | 98% | 2% | 2.858 | 3.53 | 1.1 | 0.15 | 2.75 | 3.80 | 420 | 298 | 0.58 |
| Example 10 | Mg | 0.03 | 98% | 2% | 2.861 | 3.54 | 1.06 | 0.165 | 2.75 | 3.82 | 433 | 318 | 0.59 |
| Example 11 | Mg | 0.05 | 98% | 2% | 2.861 | 3.58 | 1.10 | 0.145 | 2.80 | 2.83 | 430 | 331 | 0.64 |
| Example 12 | Ca | 0.01 | 99% | 1% | 2.849 | 3.61 | 0.70 | 0.11 | 2.76 | 3.81 | 411 | 250 | 0.51 |
| Example 13 | Ca | 0.03 | 99% | 1% | 2.851 | 3.62 | 0.72 | 0.15 | 2.73 | 3.80 | 415 | 244 | 0.51 |
| Example 14 | Ca | 0.05 | 99% | 1% | 2.852 | 3.63 | 0.72 | 0.17 | 2.72 | 3.79 | 415 | 250 | 0.53 |
| Example 15 | Ca | 0.01 | 98% | 2% | 2.858 | 3.59 | 0.81 | 0.12 | 2.78 | 3.80 | 433 | 280 | 0.52 |
| Example 16 | Ca | 0.03 | 98% | 2% | 2.857 | 3.60 | 0.81 | 0.11 | 2.79 | 3.80 | 436 | 298 | 0.52 |
| Example 17 | Ca | 0.05 | 98% | 2% | 2.860 | 3.61 | 0.83 | 0.09 | 2.81 | 3.82 | 435 | 321 | 0.54 |
| Example 18 | Al | 0.01 | 99% | 1% | 2.860 | 3.51 | 1.23 | 0.11 | 2.71 | 3.78 | 466 | 301 | 0.59 |
| Example 19 | Al | 0.03 | 99% | 1% | 2.858 | 3.53 | 1.15 | 0.14 | 2.70 | 3.76 | 415 | 261 | 0.54 |
| Example 20 | Al | 0.05 | 99% | 1% | 2.858 | 3.54 | 1.23 | 0.16 | 2.71 | 3.74 | 427 | 286 | 0.55 |
| Example 21 | Al | 0.01 | 98% | 2% | 2.855 | 3.56 | 1.24 | 0.15 | 2.75 | 3.80 | 455 | 301 | 0.57 |
| Example 22 | Al | 0.03 | 98% | 2% | 2.861 | 3.55 | 1.17 | 0.161 | 2.76 | 3.81 | 445 | 333 | 0.58 |
| Example 23 | Al | 0.05 | 98% | 2% | 2.861 | 3.57 | 1.12 | 0.142 | 2.77 | 2.83 | 427 | 341 | 0.61 |

TABLE 2

| | | | | Cycling | Cycling |
|---|---|---|---|---|---|
| | | | | capacity | capacity |
| | | | | retention | retention rate |
| | Electrolyte solution additive | | Thickness | rate at 25° C. | at 45° C. |
| | | Mass | swelling rate | (300th | (300th cycle) |
| | Type | percentage | at 85° C. | cycle) | |
| Comparative | / | / | 35% | 81% | 45% |
| example 1 | | | | | |
| Example 1 | / | / | 20% | 91% | 84% |
| Example 2 | / | / | 18% | 93% | 87% |
| Example 3 | / | / | 15% | 93% | 88% |
| Example 4 | / | / | 15% | 94% | 89% |
| Example 5 | / | / | 16% | 89% | 84% |
| Example 6 | / | / | 15% | 95% | 90% |
| Example 7 | / | / | 18% | 91% | 83% |
| Example 8 | / | / | 16% | 89% | 85% |
| Example 9 | / | / | 16% | 92% | 88% |
| Example 10 | / | / | 17% | 94% | 90% |
| Example 11 | / | / | 18% | 95% | 88% |
| Example 12 | / | | 22% | 88% | 79% |
| Example 13 | / | / | 21% | 87% | 81% |
| Example 14 | / | / | 24% | 89% | 83% |
| Example 15 | / | / | 23% | 88% | 83% |
| Example 16 | / | / | 22% | 91% | 85% |
| Example 17 | / | / | 21% | 92% | 86% |
| Example 18 | / | / | 18% | 95% | 88% |
| Example 19 | / | / | 19% | 94% | 89% |
| Example 20 | / | / | 20% | 91% | 90% |
| Example 21 | / | / | 18% | 92% | 91% |
| Example 22 | / | / | 17% | 96% | 90% |
| Example 23 | / | / | 16% | 94% | 91% |
| Example 24 | Butanedinitrile | 0.3% | 15% | 92% | 90% |
| Example 25 | Butanedinitrile | 1.2% | 10% | 92% | 91% |
| Example 26 | 1,3,6- | 2.7% | 9% | 91% | 89% |
| | hexanetricarbonitrile | | | | |
| Example 27 | 1,3,6- | 5% | 8% | 93% | 92% |
| | hexanetricarbonitrile | | | | |
| Example 28 | Butanedinitrile | 3% | 7% | 95% | 93% |
| | 1,3,6- | 4% | 6% | 96% | 93% |
| | hexanetricarbonitrile | | | | |

From the comparison of Examples 1 to 23 with Comparative example 1 in Table 1 and Table 2, it can be learned that the O2-phase layered transition metal oxide positive electrode material in this application can reduce the thickness swelling rate of the electrochemical apparatus and improve the cycling capacity retention rate at normal temperature and high temperature. When the positive electrode material is used in the electrochemical apparatus according to this application, a non-degraded voltage plateau shape can be obtained. The positive electrode materials in Examples 1 to 23 can improve the reversibility of lithium ion migration and effectively inhibit structural phase transformation. Compared with that in Comparative example 1, since the positive electrode material according to this application effectively inhibits irreversible phase transformation and improves the reversibility of lithium ion migration, the electrochemical apparatus in some embodiments of this application can effectively reduce gas production problems in high-temperature environments and improve the cycling capacity retention rate. In addition, compared with cycling at 25° C. normal temperature, the positive electrode material in this application can more effectively improve the cycling performance under 45° C. high temperature. In particular, comparison between Examples 24 to 28 and Example 1 shows that when the positive electrode material according to this application and the electrolyte solution containing a nitrile compound are used in combination in the electrochemical apparatus, the cycling performance and high-temperature performance of the electrochemical apparatus can be significantly improved. The nitrile compound mainly performs two functions: first, the antioxidant effect of the nitrile compound is compatible with the positive electrode material in this application, and the two can jointly stabilize the electrode interface film without increasing impedance, and regulate the density, toughness and uniformity of the electrode interface film; second, the nitrile compound and the positive electrode material in this application jointly act to facilitate the utilization of the plateau capacity of the positive electrode material. Therefore, adding a nitrile compound to the electrolyte solution can further improve the cycling stability of the electrochemical apparatus and reduce the thickness swelling rate.

Although some exemplary embodiments of this application have been illustrated and described, this application is not limited to the disclosed embodiments. On the contrary, those of ordinary skill in the art will recognize that modifications and changes can be made to the described embodiments without departing from the spirit and scope of this application as described in the appended claims, and these modifications and changes also fall within the protection scope of this application.

What is claimed is:

1. A positive electrode material, wherein the positive electrode material has a P63MC crystal system structure; and in an XRD pattern of the positive electrode material, peaks are present respectively at 2θ of 17.6±0.3°, 37.3±0.3°, 40.6±0.3°, and 45.2±0.3°, wherein the peak at 17.6±0.2° is a (002) peak, the peak at 37.3±0.3° is a (101) peak, the peak at 40.6±0.3° is a (102) peak, and the peak at 45.2±0.3° is a (103) peak; wherein
a ratio of a peak intensity of the (101) peak to a peak intensity of the (002) peak is 0.04 to 0.4, and a ratio of the peak intensity of the (101) peak to a peak intensity of the (103) peak is 0.4 to 3.0.

2. The positive electrode material according to claim 1, wherein the positive electrode material comprises Li element; and based on a weight of the positive electrode material, a content of the Li element is greater than 3 wt %.

3. The positive electrode material according to claim 1, wherein a unit cell of the positive electrode material satisfies at least one of the following conditions:
$$2.5 Å < a < 3. Å ; \qquad ( i )$$
$$8.5 Å < c < 10.5 Å ; or \qquad ( ii )$$
$$c / a > 2.5 . \qquad ( iii )$$

4. The positive electrode material according to claim 1, wherein in a Raman spectrum of the positive electrode material, a first peak is present at a wavelength of 496±10 cm⁻¹ and a second peak is present at 618±10 cm⁻¹, and a ratio of a peak intensity of the first peak to a peak intensity of the second peak is 0.45 to 0.68.

5. The positive electrode material according to claim 1, wherein the positive electrode material comprises a compound LiₓG_{y}(Niₐ₁Co_{b1}Mn_{c1}M_{d1})OₑQ_{f}, wherein 0.5<x+y≤0.8, 0≤a1≤1, 0≤b1≤1, 0≤c1≤1, 0≤d1≤1, 1.8≤e+f≤2.2, and a1, b1, c1, d1 are not simultaneously 0; wherein
the element G comprises Na and/or K; the element M comprises at least one of Ca, Sr, Ba, Al, Fe, B, Mg, Si, S, Ti, Cr, Cu, Zn, Ga, Zr, Mo, W, Nb, In, Sn, Pb, Sb, Ce, La, or Hf; and the element Q comprises at least one of F, Cl, Br, I, N, or P.

6. The positive electrode material according to claim 1, wherein a voltage-capacity differential curve (dQ/dV curve), obtained when a button cell formed by the positive electrode material and lithium metal is charged and discharged at a current of 0.04 C in a voltage range of 2.5V to 4.5V, has at least one pair of redox peaks respectively in a voltage range of 2.5V to 3.1V and a voltage range of 3.5V to 4.5V.

7. The positive electrode material according to claim 1, wherein based on a mass of the positive electrode material, when a button cell formed by the positive electrode material and lithium metal is charged and discharged at a current of 0.04 C in a voltage range of 2.5V to 3.1V, a peak intensity of an obtained voltage-capacity differential curve (dQ/dV curve) is 400 mAh/g/V to 1000 mAh/g/V; and/or
based on the mass of the positive electrode material, when charge and discharge are performed at a current of 0.04 C in a voltage range of 3.5V to 4.5V, a peak intensity of an obtained voltage-capacity differential curve (dQ/dV curve) is 200 mAh/g/V to 600 mAh/g/V.

8. The positive electrode material according to claim 1, wherein for a button cell formed by the positive electrode material and lithium metal, when charged and discharged at a current of 0.04 C in a voltage range of 2.5V to 4.5V, a discharge curve in an obtained voltage-capacity curve has a sloping plateau at 3.5V to 4.3V, a specific capacity of the discharge curve in a range of 3.5V to 4.3 V is Q1, and a total specific capacity in the range of 2.5V to 4.5V is Q2, wherein 0.4≤Q1/Q2<0.7.

9. The positive electrode material according to claim 1, wherein when a button cell formed by the positive electrode material and lithium metal is charged to 4.5V, peaks are present respectively at 2θ of 18.6±0.3°, 37.9±0.3°, 41.5±0.3°, and 47.0±0.3° in the XRD pattern of the positive electrode material, and/or
when the button cell formed by the positive electrode material and lithium metal is discharged to 2.5V, peaks are present respectively at 2θ of 17.9±0.3°, 36.6±0.3°, 37.0±0.3°, 40.5±0.3°, and 45.7±0.3° in the XRD pattern of the positive electrode material.

10. The positive electrode material according to claim 1, wherein for a button cell formed by the positive electrode material and lithium metal, at a rate of 0.1 C in a voltage range of 2.8V to 4.5V, in a voltage-capacity differential curve (dQ/dV curve), a peak voltage of a reduction peak of 2.5V to 3.1 V is V1, and a peak voltage of a reduction peak of 3.5V to 4.3V is V2, wherein 0.55≤V1/V2≤0.85.

11. An electrochemical apparatus, comprising a positive electrode, wherein the positive electrode comprises the positive electrode material according to claim 1.

12. The electrochemical apparatus according to claim 11, wherein the electrochemical apparatus further comprises an electrolyte solution, wherein the electrolyte solution comprises a nitrile compound; and the nitrile compound comprises at least one of the following compounds:

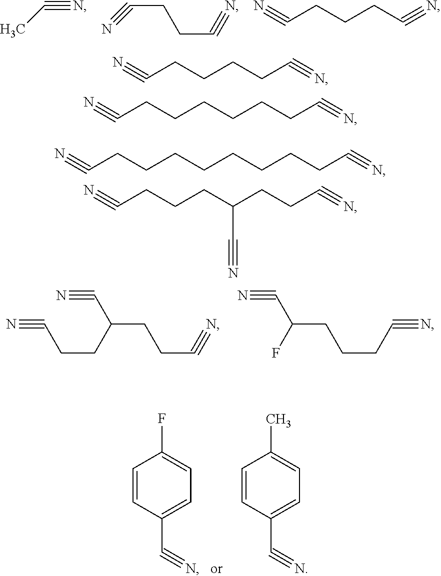

13. The electrochemical apparatus according to claim 12, wherein based on a mass of the electrolyte solution, a mass percentage of the nitrile compound is 0.1% to 8%.

14. An electronic apparatus, comprising the electrochemical apparatus according to claim 11.

15. The electronic apparatus according to claim 14, wherein the positive electrode material comprises Li element; and based on a weight of the positive electrode material, a content of the Li element is greater than 3 wt %.

16. The electronic apparatus according to claim 14, wherein a unit cell of the positive electrode material satisfies at least one of the following conditions:
$$2.5 Å < a < 3. Å ; \qquad ( i )$$
$$8.5 Å < c < 10.5 Å ; or \qquad ( ii )$$
$$c / a > 2.5 . \qquad ( iii )$$

17. The electronic apparatus according to claim 14, wherein in a Raman spectrum of the positive electrode material, a first peak is present at a wavelength of 496±10 cm⁻¹ and a second peak is present at 618±10 cm⁻¹, and a ratio of a peak intensity of the first peak to a peak intensity of the second peak is 0.45 to 0.68.

18. The electronic apparatus according to claim 14, wherein the positive electrode material comprises a compound LiₓG_{y}(Niₐ₁CO_{b1}Mn_{c1}M_{d1})OₑQ_{f}, wherein 0.5<x+y≤0.8, 0≤a1≤1, 0≤b1≤1, 0≤c1≤1, 0≤d1≤1, 1.8≤e+f≤2.2, and a1, b1, c1, d1 are not simultaneously 0; wherein
the element G comprises Na and/or K; the element M comprises at least one of Ca, Sr, Ba, Al, Fe, B, Mg, Si, S, Ti, Cr, Cu, Zn, Ga, Zr, Mo, W, Nb, In, Sn, Pb, Sb, Ce, La, or Hf; and the element Q comprises at least one of F, Cl, Br, I, N, or P.

19. The electronic apparatus according to claim 14, wherein a voltage-capacity differential curve (dQ/dV curve), obtained when a button cell formed by the positive electrode material and lithium metal is charged and discharged at a current of 0.04 C in a voltage range of 2.5V to 4.5V, has at least one pair of redox peaks respectively in a voltage range of 2.5V to 3.1V and a voltage range of 3.5V to 4.5V.

20. The electronic apparatus according to claim 14, wherein the electrochemical apparatus further comprises an electrolyte solution, wherein the electrolyte solution comprises a nitrile compound; and the nitrile compound comprises at least one of the following compounds: 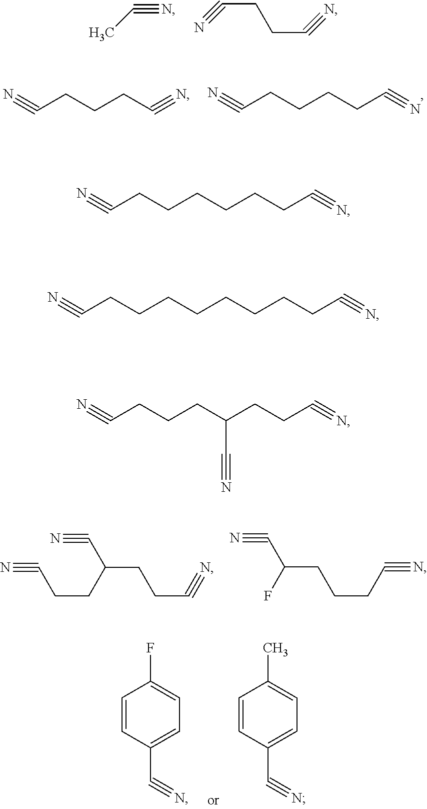
wherein based on a mass of the electrolyte solution, a mass percentage of the nitrile compound is 0.1% to 8%.
